(19) United States
(12) Patent Application Publication
(10) Pub. No.: US 2025/0330208 A1
(43) Pub. Date: Oct. 23, 2025

(54) TRANSMITTER AND METHOD FOR REDUCING LOCAL OSCILLATION LEAKAGE IN TRANSMITTER

(71) Applicant: Realtek Semiconductor Corp., Hsinchu (TW)

(72) Inventors: Beng-Meng Chen, HsinChu (TW); Chien-Jung Huang, HsinChu (TW); Yi-Hua Lu, HsinChu (TW)

(73) Assignee: Realtek Semiconductor Corp., Hsinchu (TW)

(21) Appl. No.: 19/094,995

(22) Filed: Mar. 30, 2025

(30) Foreign Application Priority Data
Apr. 23, 2024 (TW) 113115027

(51) Int. Cl. H04B 1/525; H03G 3/30; H04B 17/12

(52) U.S. Cl. CPC H04B 1/525; H03G 3/3036; H04B 17/12; H03G 2201/103

(57) ABSTRACT

A transmitter and a method for reducing local oscillation (LO) leakage in the transmitter are provided. The transmitter includes an amplifier, a mixer, a self-mixer, a first calibration signal source, a second calibration signal source and a calibration logic circuit. The amplifier generates an amplified baseband signal, and the mixer performs an up-conversion upon the amplified baseband signal to generate a radio frequency (RF) signal, wherein the self-mixer performs self-mixing according to the RF signal to generate a feedback signal. In a first phase, the calibration logic circuit controls a first signal output from the first calibration signal source to the amplifier, to minimize a direct-current (DC) signal within the amplified baseband signal. In a second phase, the calibration logic circuit controls a second signal output from the second calibration signal source to the mixer, to minimize a feedback baseband signal within the feedback signal.

### BACKGROUND OF THE INVENTION

### 1. Field of the Invention

The present invention is related to wireless communication circuit designs, and more particularly, to a transmitter and a method for reducing local oscillation (LO) leakage in the transmitter.

### 2. Description of the Prior Art

In wireless communication fields, analog circuits on a signal output path typically have direct current (DC) offsets. After the DC offsets are up-converted by a mixer, some signal components which do not belong to a transmitted signal may occur in a signal band. This effect is referred to as local oscillation (LO) leakage. In order to solve the problem of LO leakage, various calibration mechanisms have been proposed in the related arts. These calibration mechanisms have some disadvantages. For example, a related art evaluates a calibration condition of a DC offset of a calibration target circuit by detecting power of a specific frequency. When the calibration target circuit outputs a signal with higher power for requirements of the calibration mechanism, however, signal components of the signals on the specific frequency become interference sources due to signal coupling, thereby making it difficult to properly evaluate the DC offset of the calibration target circuit. In addition, the calibration target circuit has different DC offsets under different gain settings. The calibration target circuit needs to operate under different gain settings in practice, making DC offset calibration for a single gain setting hard to satisfy the requirements of a wide signal dynamic range.

Thus, there is a need for a novel architecture and an associated method, which can solve the problem of the related art without introducing any side effect or in a way that is less likely to introduce side effects.

### SUMMARY OF THE INVENTION

An objective of the present invention is to provide a transmitter and a method for reducing local oscillation (LO) leakage in the transmitter, in order to properly calibrate direct current (DC) offsets of one or more analog circuit within the transmitter.

At least one embodiment of the present invention provides a transmitter. The transmitter comprises an analog amplifier, a mixer, a self-mixer, a first calibration signal source, a second calibration signal source and a calibration logic circuit, wherein the first calibration signal source is coupled to the analog amplifier, the second calibration signal source is coupled to the mixer, and the calibration logic circuit is coupled to the first calibration signal source and the second calibration signal source. The analog amplifier is configured to amplify a baseband signal to generate an amplified baseband signal. The mixer is configured to perform an up-conversion upon the amplified baseband signal to generate a radio frequency (RF) signal. The self-mixer is configured to perform self-mixing according to the RF signal to generate a feedback signal. The first calibration signal source is configured to output a first calibration signal to the analog amplifier. The second calibration signal source is configured to output a second calibration signal to the mixer. In a first calibration phase, the calibration logic circuit controls the first calibration signal according to a DC signal within the amplified baseband signal, to minimize the DC signal. In a second calibration phase, the calibration logic circuit controls the second calibration signal according to a feedback baseband signal within the feedback signal, to minimize the feedback baseband signal.

At least one embodiment of the present invention provides a method for reducing (LO leakage in a transmitter. The method comprises: in a first calibration phase, utilizing an analog amplifier of the transmitter to amplify a baseband signal to generate an amplified baseband signal; in the first calibration phase, utilizing a calibration logic circuit of the transmitter to control a first calibration signal source of the transmitter to output a first calibration signal to the analog amplifier according to a DC signal within the amplified baseband signal, in order to minimize the DC signal; in a second calibration phase after the first calibration phase, utilizing a mixer of the transmitter to perform an up-conversion upon the amplified baseband signal to generate a RF signal; in the second calibration phase, utilizing a self-mixer of the transmitter to perform self-mixing according to the RF signal to generate a feedback signal; and in the second calibration phase, utilizing the calibration logic circuit to control a second calibration signal source of the transmitter to output a second calibration signal to the mixer according to a feedback baseband signal within the feedback signal, in order to minimize the feedback baseband signal.

The transmitter and the method provided by the embodiments of the present invention can calibrate a DC offset of the analog amplifier according to a DC component within a signal output from the analog amplifier. In comparison with detecting a baseband signal which is generated by up-converting and down-converting the signal output from the analog amplifier, the present invention can obtain a calibration result with higher precision. In addition, the embodiments of the present invention will not greatly increase additional costs. Thus, the present invention can solve the problem of the related art without introducing any side effect or in a way that is less likely to introduce side effects.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a transmitter according to an embodiment of the present invention.

FIG. 2 is a diagram illustrating calibration of a direct current (DC) offset of an analog amplifier in the transmitter shown in FIG. 1 according to an embodiment of the present invention.

FIG. 3 is a diagram illustrating calibration of a DC offset of a mixer in the transmitter shown in FIG. 1 according to an embodiment of the present invention.

FIG. 4 is a diagram illustrating a working flow of a method for reducing local oscillation (LO) leakage in a transmitter according to an embodiment of the present invention.

### DETAILED DESCRIPTION

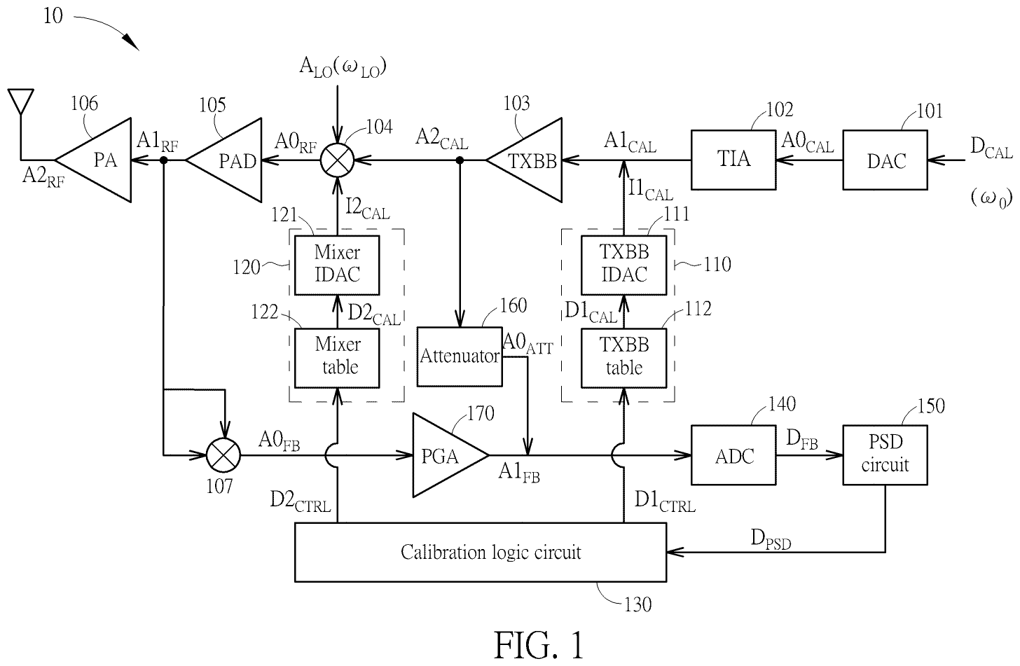

FIG. 1 is a diagram illustrating a transmitter 10 according to an embodiment of the present invention. As shown in FIG. 1, the transmitter 10 may comprise a digital-to-analog converter (DAC) 101, a transimpedance amplifier (TIA) 102 coupled to the DAC 101, an analog amplifier such as a transmitter baseband (TXBB) amplifier 103 (labeled “TXBB” in figures for brevity) coupled to the TIA 102, a mixer 104 coupled to the TXBB amplifier 103, a power amplifier driver (PAD) 105 coupled to the mixer 104, a power amplifier (PA) 106 coupled to the PAD 105, a self-mixer 107 coupled to the PAD 105, a first calibration signal source such as an amplifier calibration signal source 110 coupled to the TXBB amplifier 103, a second calibration signal source such as a mixer calibration signal source 120 coupled to the mixer 104, and a calibration logic circuit 130 coupled to the amplifier calibration signal source 110 and a mixer calibration signal source 120.

In this embodiment, the DAC 101 may perform a digital-to-analog conversion upon a digital test signal D_{CAL} to output an analog test signal A0_{CAL}, and the TIA 102 may perform a current-to-voltage conversion upon the analog test signal A0_{CAL} (e.g. a current test signal) to output a baseband signal A1_{CAL} (e.g. a voltage test signal). The TXBB amplifier 103 is configured to amplify the baseband signal A1_{CAL} to generate an amplified baseband signal A2_{CAL}, and the mixer 104 is configured to perform an up-conversion upon the amplified baseband signal A2_{CAL} (e.g. performing the up-conversion based on a local oscillation (LO) signal A_{LO} which has a frequency equal to ω_{LO}) to generate a radio frequency (RF) signal A0_{RF}. In addition, the PAD 105 may generate a RF signal A1_{RF} according to the RF signal A0_{RF}, in order to drive the PA 106. The PA 106 may accordingly output an RF signal A2_{RF} to an antenna for wireless communications. When the transmitter 10 operates in a calibration mode, the self-mixer 107 is configured to perform self-mixing according to the RF signal A0_{RF} to generate a feedback signal A0_{FB}. In this embodiment, the self-mixer 107 may receive the RF signal A1_{RF} (which is generated according to the RF signal A0_{RF}) output from the PAD 105, and perform self-mixing upon the RF signal A1_{RF} to generate the feedback signal A0_{FB}. In some embodiments, the self-mixer 107 may receive the RF signal A0_{RF} output from the mixer 104, and perform self-mixing upon the RF signal A0_{RF} to generate the feedback signal A0_{FB}. In some embodiments, the self-mixer 107 may receive the RF signal A2_{RF} output from the PA 106, and perform self-mixing upon the RF signal A2_{RF} to generate the feedback signal A0_{FB}.

In the transmitter 10, factors affecting LO leakage comprise a direct current (DC) offset V_{DC,TXBB} of the TXBB amplifier 103 and a DC offset V_{DC,MIXER} of the mixer 104. For example, the LO leakage of the transmitter 10 may be positively related to (G_{TXBB}×V_{DC,TXBB}+V_{DC,MIXER}), where GTXBB may represent a gain of the TXBB amplifier 103. In this embodiment, the amplifier calibration signal source 110 is configured to output an amplifier calibration signal I1_{CAL} to the TXBB amplifier 103, in order to calibrate the DC offset V_{DC,TXBB} of the TXBB amplifier 103, and the mixer calibration signal source 120 is configured to output a mixer calibration signal I2_{CAL} to the mixer 104, in order to calibrate the DC offset V_{DC,MIXER} of the mixer 104. In an amplifier calibration phase, the calibration logic circuit 130 may control the amplifier calibration signal I1_{CAL} according to a DC signal within the amplified baseband signal A2_{CAL}, to minimize the DC signal (e.g. controlling the amplifier calibration signal source 110 by controlling a signal D1_{CTRL} to adjust a value of the amplifier calibration signal I1_{CAL}, in order to find the value of the amplifier calibration signal I1_{CAL} which minimizes the DC signal). In a mixer calibration phase after the amplifier calibration phase, the calibration logic circuit 130 may control the mixer calibration signal I2_{CAL} according to a feedback baseband signal within the feedback signal A0_{FB} (e.g. a signal component having a specific frequency in the feedback signal A0_{FB}), to minimize the feedback baseband signal (e.g. controlling the mixer calibration signal source 120 by controlling a signal D2_{CTRL} to adjust a value of the mixer calibration signal I2_{CAL}, in order to find the value of the mixer calibration signal I2_{CAL} which minimizes the feedback baseband signal).

In this embodiment, a frequency of the digital test signal DCAL is ω₀, and therefore frequencies of both the analog test signal A0_{CAL} and the baseband signal A1_{CAL} are ω₀, where the DC offset V_{DC,TXBB} of the TXBB amplifier 103 may be carried by a DC frequency of the amplified baseband signal A2_{CAL}, making the amplified baseband signal A2_{CAL} comprise a signal component having a frequency equal to @o (which corresponds to the digital test signal D_{CAL}) and a signal component having a frequency equal to zero such as the DC signal (which corresponds to the DC offset V_{DC,TXBB} of the TXBB amplifier 103). More particularly, a magnitude of the DC signal may represent a magnitude of the DC offset V_{DC,TXBB} of the TXBB amplifier 103. Thus, the calibration logic circuit 130 may calibrate the DC offset V_{DC,TXBB} of the TXBB amplifier 103 by minimizing the DC signal. After the DC offset V_{DC,TXBB} of the TXBB amplifier 103 is minimized (e.g. being eliminated), the mixer 104 may perform an up-conversion upon the amplified baseband signal A2_{CAL} (the signal component having the frequency equal to zero therein is already minimized and is therefore omitted) to make the RF signal A0_{RF} (or any of the RF signals A1_{RF} and A2_{RF}) comprise a signal component (assuming that a signal amplitude thereof is A) having a frequency equal to (ω_{LO}+ω₀) and a signal component (assuming that a signal amplitude thereof is C) having a frequency equal to (ω_{LO}−ω₀), where the DC offset V_{DC,MIXER} of the mixer 104 may be up-converted, making the RF signal A0_{RF} (or any of the RF signals A1_{RF} and A2_{RF}) further comprise a signal component (assuming that a signal amplitude thereof is B) having a frequency equal to ω_{LO}. Thus, the amplitude B of the signal component having the frequency equal to ω_{LO} in the RF signal A0_{RF} (or any of the RF signals A1_{RF} and A2_{RF}) may represent a magnitude of the DC offset V_{DC,MIXER} of the mixer 104.

For better comprehension, the signal component having the frequency equal to (ω_{LO}+ω₀) and the amplitude equal to A in the RF signal A0_{RF} (or any of the RF signals A1_{RF} and A2_{RF}) may be represented by A(ω_{LO}+ω₀), the signal component having the frequency equal to (ω_{LO}−ω₀) and the amplitude equal to C in the RF signal A0_{RF} (or any of the RF signals A1_{RF} and A2_{RF}) may be represented by C(ω_{LO}−ω₀), and the signal component having the frequency equal to ω_{LO} and the amplitude equal to B in the RF signal A0_{RF} (or any of the RF signals A1_{RF} and A2_{RF}) may be represented by B(ω_{LO}). For brevity, the following descriptions take the architecture of the self-mixer 107 performing self-mixing upon the RF signal A1_{RF} as an example, where related details of the architecture of the self-mixer 107 performing self-mixing upon the RF signal A0_{RF} or A2_{RF} may be deduced by analogy. When the self-mixer 107 performs self-mixing upon the RF signal A1_{RF}, the signal component A(ω_{LO}+ω₀) within the RF signal A1_{RF} received by a first input terminal of the self-mixer 107 (e.g. a left-side input terminal of the self-mixer 107 shown in the figures) may be mixed with the signal components A(ω_{LO}+ω₀), B(ω_{LO}) and C(ω_{LO}−ω₀) within the RF signal A1_{RF} received by a second input terminal of the self-mixer 107 (e.g. an upper-side input terminal of the self-mixer 107 shown in the figures), respectively, to generate a signal component having the DC frequency (with an amplitude equal to (G_{SELFMIXER}×A×A)), a signal component having the frequency equal to ω₀ (with an amplitude equal to (G_{SELFMIXER}×B×A)) and a signal component having a frequency equal to (2×ω₀) (with an amplitude equal to (G_{SELFMIXER}×C×A)) in the feedback signal A0_{FB}, where G_{SELFMIXER} may represent a conversion gain of the self-mixer 107. The signal component B(ω_{LO}) within the RF signal A1_{RF} received by the first input terminal of the self-mixer 107 (e.g. the left-side input terminal of the self-mixer 107 shown in the figures) may be mixed with the signal components A(ω_{LO}+ω₀), B(ω_{LO}) and C(ω_{LO}−ω₀) within the RF signal A1_{RF} received by the second input terminal of the self-mixer 107 (e.g. the upper-side input terminal of the self-mixer 107 shown in the figures), respectively, to generate a signal component having the DC frequency (with an amplitude equal to (G_{SELFMIXER}×B×B)) and a signal component having the frequency equal to ω₀ (with amplitudes equal to (G_{SELFMIXER}×A×B) and (G_{SELFMIXER}×C×B)) in the feedback signal A0_{FB}. The signal component C(ω_{LO}−ω₀) within the RF signal A1_{RF} received by the first input terminal of the self-mixer 107 (e.g. the left-side input terminal of the self-mixer 107 shown in the figures) may be mixed with the signal components A(ω_{LO}+ω₀), B(ω_{LO}) and C(ω_{LO}−ω₀) within the RF signal A1_{RF} received by the second input terminal of the self-mixer 107 (e.g. the upper-side input terminal of the self-mixer 107 shown in the figures), respectively, to generate a signal component having the DC frequency (with an amplitude equal to (G_{SELFMIXER}×C×C)), a signal component having the frequency equal to ω₀ (with an amplitude equal to (G_{SELFMIXER}×B×C)) and a signal component having a frequency equal to (2×ω₀) (with an amplitude equal to (G_{SELFMIXER}×A×C)) in the feedback signal A0_{FB}. Thus, a magnitude of the signal component having the frequency equal to the DC frequency in the feedback signal A0_{FB} may be determined according to ((G_{SELFMIXER}×A×A)+(G_{SELFMIXER}×B×B)+(G_{SELFMIXER}×C×C)), a magnitude of the signal component having the frequency equal to ω₀ in the feedback signal A0_{FB} may be determined according to ((G_{SELFMIXER}×B×A)+(G_{SELFMIXER}×A×B)+(G_{SELFMIXER}×C×B)+(G_{SELFMIXER}×B×C)), and a magnitude of the signal component having the frequency equal to (2×ω₀) in the feedback signal A0_{FB} may be determined according to ((G_{SELFMIXER}×C×A)+(G_{SELFMIXER}×A×C)). In view of the above, all of the signal components having the frequency equal to ω₀ in the feedback signal A0_{FB} are related to the magnitude of the DC offset V_{DC,MIXER} of the mixer 104 (as all of the signal components having the frequency equal to ω₀ comprise the amplitude B), and the signal components having the frequency equal to the DC frequency or (2×ω₀) in the feedback signal A0_{FB} comprise at least one portion (e.g. the portions which do not comprise the amplitude B) that are not related to the magnitude of the DC offset V_{DC,MIXER} of the mixer 104. Based on the above reasons, the calibration logic circuit 130 preferably controls the mixer calibration signal I2_{CAL} according to the signal component having the frequency equal to ω₀ in the feedback signal A0_{FB}, to minimize the signal component having the frequency equal to ω₀ in the feedback signal A0_{FB}. That is, when a frequency of the baseband signal A1_{CAL} is ω₀, the feedback baseband signal within the feedback signal A0_{FB} is the signal component having the frequency ω₀ in the feedback signal A0_{FB}. Thus, the calibration logic circuit 130 may calibrate the DC offset V_{DC,MIXER} of the mixer 104 by minimizing the feedback baseband signal.

In addition, the transmitter 10 may further comprise an analog-to-digital converter (ADC) 140 and a power spectral density (PSD) circuit 150, where the PSD circuit 150 is coupled to the ADC 140 and the calibration logic circuit 130. In this embodiment, the ADC 140 is configured to perform an analog-to-digital conversion according to the amplified baseband signal A2_{CAL} to generate a first digital signal (e.g. the digital signal D_{FB} obtained in the amplifier calibration phase) in the amplifier calibration phase, and perform the analog-to-digital conversion according to the feedback signal A0_{FB} to generate a second digital signal (e.g. the digital signal D_{FB} obtained in the mixer calibration phase) in the mixer calibration phase. The PSD circuit 150 is configured to calculate power of a signal component having a frequency equal to zero within the first digital signal to obtain a first calculation result (e.g. a calculation result D_{PSD} obtained in the amplifier calibration phase), and calculate power of a signal component having the frequency equal to ω₀ within the second digital signal to obtain a second calculation result (e.g. the calculation result D_{PSD} obtained in the mixer calibration phase), where the first calculation result and the second calculation result represent power of the DC signal (which correspond to the DC offset V_{DC,TXBB} of the TXBB amplifier 103) and power of the feedback baseband signal (which correspond to the DC offset V_{DC,MIXER} of the mixer 104), respectively. More particularly, the calibration logic circuit 130 may control the amplifier calibration signal I1_{CAL} according to the first calculation result, and control the mixer calibration signal I2_{CAL} according to the second calculation result.

In this embodiment, the transmitter 10 may further comprise an attenuator 160, where the attenuator 160 is coupled between the TXBB amplifier 103 and the ADC 140. Under some conditions, a signal range of the amplified baseband signal A2_{CAL} may exceed a dynamic range of the ADC 140 to thereby make output of the ADC 140 reach saturation. In order to prevent saturation of the ADC 140, the attenuator 160 may reduce an amplitude of the amplified baseband signal A2_{CAL} to generate an attenuated baseband signal A0_{ATT} in the amplifier calibration phase. Thus, the ADC 140 may perform the analog-to-digital conversion upon the attenuated baseband signal A0_{ATT} (which is generated according to the amplified baseband signal A2_{CAL}) to generate the digital signal D_{FB} in the amplifier calibration phase. In addition, the transmitter may further comprise a programmable-gain amplifier (PGA) 170, where the PGA 170 is coupled between the self-mixer 107 and the ADC 140. The PGA 170 is configured to adjust an amplitude of the feedback signal A0_{FB} to generate an adjusted feedback signal A1_{FB} in the mixer calibration phase, in order to ensure that the amplitude of the adjusted feedback signal A1_{FB} meets requirement of the dynamic range of the ADC 140, and the ADC 140 may perform the analog-to-digital conversion upon the adjusted feedback signal A1_{FB} (which is generated according to the feedback signal A0_{FB}) to generate the digital signal D_{FB} in the mixer calibration phase.

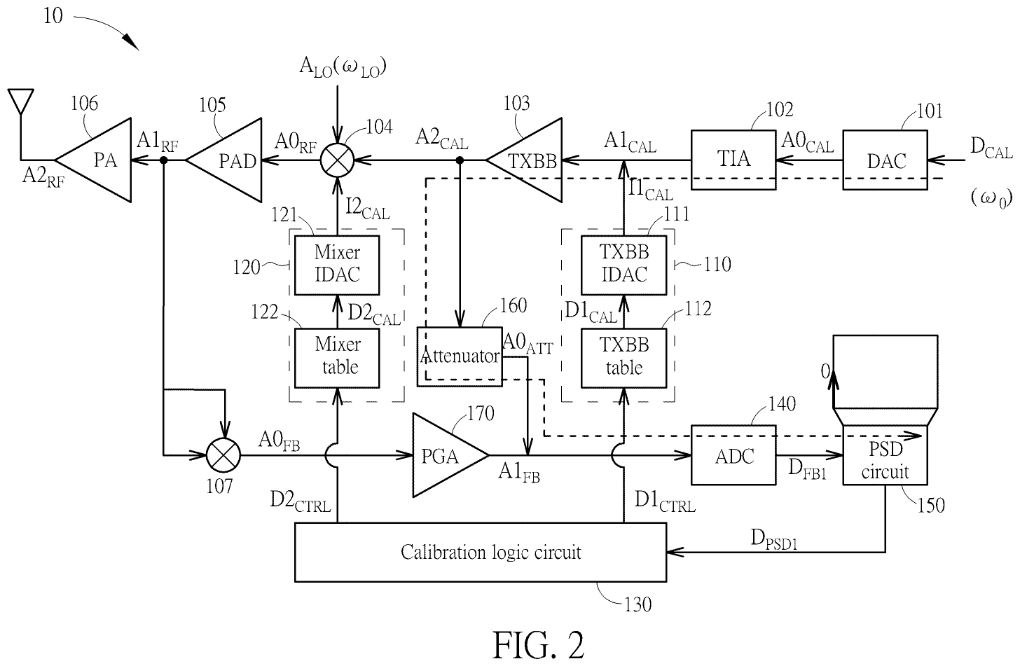

FIG. 2 is a diagram illustrating calibration of the DC offset V_{DC,TXBB} of the TXBB amplifier 103 in the transmitter 10 shown in FIG. 1 according to an embodiment of the present invention., where an associated test signal path is indicated by a dashed arrow. More particularly, the ADC 140 may perform the analog-to-digital conversion upon the attenuated baseband signal A0_{ATT} to output a digital signal D_{FB1} in the amplifier calibration phase (which may be regarded as an example of the digital signal D_{FB} obtained in the amplifier calibration phase mentioned above), and the PSD circuit 150 may calculate power of the signal component having the frequency equal to zero in the digital signal D_{FB1}, to obtain a calculation result D_{PSD1} (which may be an example of the calculation result D_{PSD} obtained in the amplifier calibration phase mentioned above).

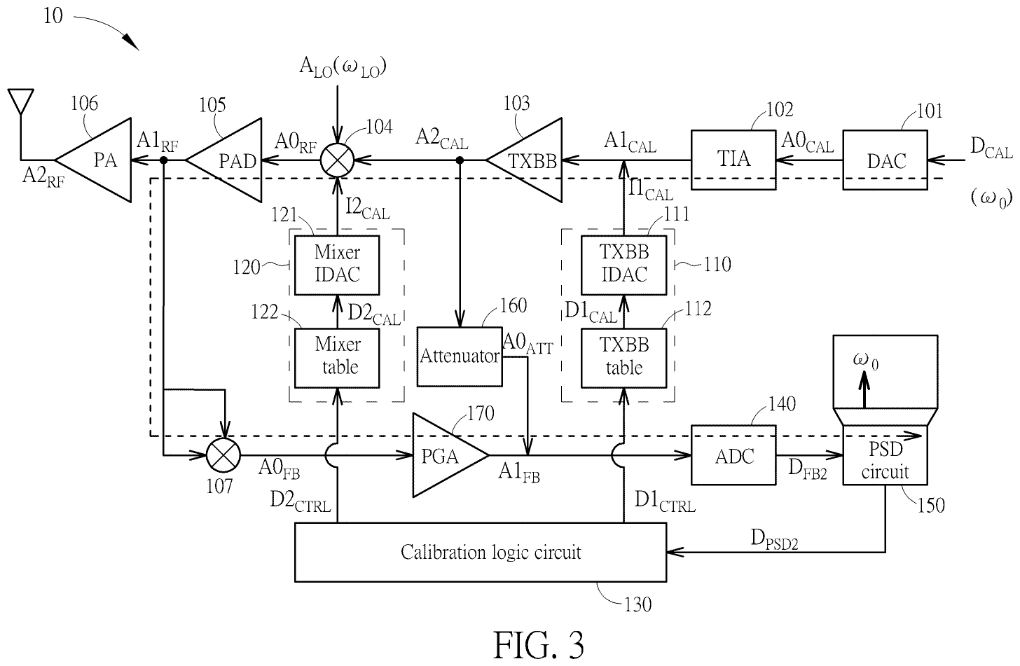

FIG. 3 is a diagram illustrating calibration of the DC offset V_{DC,MIXER} of the mixer 104 in the transmitter 10 shown in FIG. 1 according to an embodiment of the present invention, where an associated test signal path is indicated by a dashed arrow. More particularly, the ADC 140 may perform the analog-to-digital conversion upon the adjusted feedback signal A1_{FB} (which is output from the PGA 170) to output a digital signal D_{FB2} in the mixer calibration phase (which may be regarded as an example of the digital signal D_{FB} obtained in the mixer calibration phase mentioned above), and the PSD circuit 150 may calculate power of the signal component having the frequency equal to ω₀ in the digital signal D_{FB2}, to obtain a calculation result D_{PSD2} (which may be an example of the calculation result D_{PSD} obtained in the mixer calibration phase mentioned above).

It should be noted that the TXBB amplifier 103 may have multiple candidate amplification gains, where when an amplification gain of the TXBB amplifier 103 changes, the DC offset V_{DC,TXBB} of the TXBB amplifier 103 may change. If calibration is performed under only one of the multiple candidate amplification gains and the calibration result thereof is applied to all of the multiple candidate amplification gains, the LO leakage problem of the transmitter 10 will occur again when the amplification gain of the TXBB amplifier 103 changes. Thus, the amplifier calibration signal source 110 may comprise a TXBB amplifier calibration table 112 (labeled “TXBB table” in figures for brevity) and a current-type DAC 111 (labeled “TXBB IDAC” in figures for better comprehension) corresponding to the TXBB amplifier 103, where the current-type DAC 111 is coupled to the TXBB amplifier calibration table 112. For example, the current-type DAC 111 is configured to adjust a DC bias value of the TXBB amplifier 103. The TXBB amplifier calibration table 112 is configured to record multiple digital amplifier calibration values corresponding to the multiple candidate amplification gains of the TXBB amplifier 103 (e.g. calibration values respectively obtained under settings of the multiple candidate amplification gains), where the TXBB amplifier calibration table 112 may output a corresponding digital amplifier calibration value (e.g. a digital amplifier calibration value D1_{CAL}) among the multiple digital amplifier calibration values in response to the amplification gain of the TXBB amplifier 103 being set to a specific amplification gain among the multiple candidate amplification gains, and the current-type DAC 111 is configured to output the amplifier calibration signal I1_{CAL} according to the corresponding digital amplifier calibration value (e.g. the digital amplifier calibration value D1_{CAL}).

Similarly, the mixer 104 may have multiple candidate conversion gains, where when a conversion gain of the mixer 104 changes, the DC offset V_{DC,MIXER} of the mixer 104 may change. Thus, the mixer calibration signal source 120 may comprise a mixer calibration table 122 (labeled “Mixer table” in figures for brevity) and a current-type DAC 121 (labeled “Mixer IDAC” for better comprehension) corresponding to the mixer 104, where the current-type DAC 121 is coupled to the mixer calibration table 122. For example, the current-type DAC121 is configured to adjust a DC bias value of the mixer 104. The mixer calibration table 122 is configured to record multiple digital mixer calibration values corresponding to the multiple candidate conversion gains of the mixer 104 (e.g. calibration values respectively obtained under settings of the multiple candidate conversion gains), where the mixer calibration table 122 may output a corresponding digital mixer calibration value (e.g. a digital mixer calibration value D2_{CAL}) among the multiple digital mixer calibration values in response to the conversion gain of the mixer 104 being set to a specific conversion gain among the multiple candidate conversion gains, and the current-type DAC 121 is configured to output the mixer calibration signal I2_{CAL} according to the corresponding digital mixer calibration value (e.g. the digital mixer calibration value D2_{CAL}).

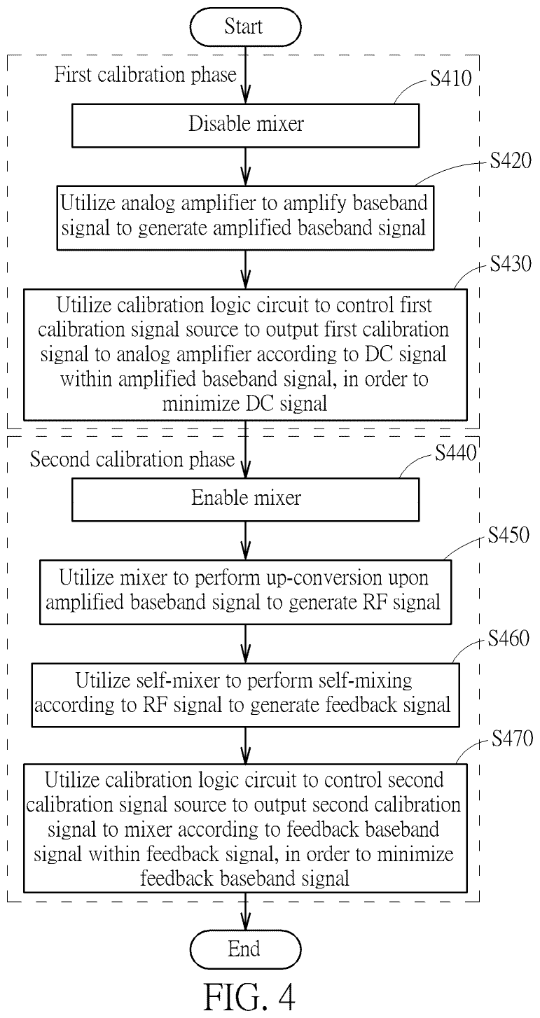

FIG. 4 is a diagram illustrating a working flow of a method for reducing LO leakage (e.g. reducing the LO leakage by calibrating, reducing or eliminating the DC offset V_{DC,TXBB} of the TXBB amplifier 103 and the DC offset V_{DC,MIXER} of the mixer 104) in a transmitter (e.g. the transmitter 10 shown in FIG. 1) according to an embodiment of the present invention, where Steps S410 to S430 belong to a first calibration phase (e.g. the amplifier calibration phase mentioned above), and Steps S440 to S470 belong to a second calibration phase (e.g. the mixer calibration phase mentioned above). It should be noted that the working flow shown in FIG. 4 is for illustrative purposes only, and is not meant to be a limitation of the present invention. For example, one or more steps may be added, deleted or modified in the working flow shown in FIG. 4. In addition, if a same result can be obtained, these steps do not have to be executed in the exact order shown in FIG. 4.

In Step S410, the transmitter may disable a mixer therein (e.g. the mixer 104 shown in FIG. 1).

In Step S420, the transmitter may utilize an analog amplifier therein (e.g. the TXBB amplifier 103 shown in FIG. 1) to amplify a baseband signal to generate an amplified baseband signal.

In Step S430, the transmitter may utilize a calibration logic circuit therein (e.g. the calibration logic circuit 130) to control a first calibration signal source of the transmitter to output a first calibration signal to the analog amplifier according to a DC signal within the amplified baseband signal, in order to minimize the DC signal.

In Step S440, the transmitter may enable the mixer.

In Step S450, the transmitter may utilize the mixer to perform an up-conversion upon the amplified baseband signal to generate a RF signal.

In Step S460, the transmitter may utilize a self-mixer therein (e.g. the self-mixer 107) to perform self-mixing according to the RF signal to generate a feedback signal.

In Step S470, the transmitter may utilize the calibration logic circuit to control a second calibration signal source of the transmitter to output a second calibration signal to the mixer according to a feedback baseband signal within the feedback signal, in order to minimize the feedback baseband signal.

To summarize, the present invention detects the amplified baseband signal A2_{CAL} (or the attenuated baseband signal A0_{ATT}) without performing up-conversion or down-conversion. Under this condition, information of the DC offset V_{DC,TXBB} of the TXBB amplifier 103 is carried on the DC frequency instead of ω₀. Thus, when the amplification gain of the TXBB amplifier 103 increases, therefore making the power of the signal component having the frequency equal to ω₀ in the amplified baseband signal A2_{CAL} (or the attenuated baseband signal A0_{ATT}) increase, detection of information of the DC offset V_{DC,TXBB} will not be interfered with. In addition, the amplification gain of the TXBB amplifier 103 may be minimized when calibrating the DC offset V_{DC,MIXER} of the mixer 104, and the DC offset V_{DC,TXBB} of the TXBB amplifier 103 is already calibrated at this moment. Thus, the DC offset V_{DC,MIXER} can be obtained by detecting the power of the signal component having the frequency equal to ω₀ in the feedback signal A0_{FB} (or the adjusted feedback signal A1_{FB}). Furthermore, by establishing a calibration table which records the calibration values for different gain values, the present invention can properly calibrate the DC offset V_{DC,TXBB} of the TXBB amplifier 103 and the DC offset V_{DC,MIXER} of the mixer 104 under various gain settings. Thus, the present invention can effectively solve the problem of the related art.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A transmitter, comprising:
an analog amplifier, configured to amplify a baseband signal to generate an amplified baseband signal;
a mixer, configured to perform an up-conversion upon the amplified baseband signal to generate a radio frequency (RF) signal;
a self-mixer, configured to perform self-mixing according to the RF signal to generate a feedback signal;
a first calibration signal source, coupled to the analog amplifier, configured to output a first calibration signal to the analog amplifier;
a second calibration signal source, coupled to the mixer, configured to output a second calibration signal to the mixer; and
a calibration logic circuit, coupled to the first calibration signal source and the second calibration signal source, wherein:
in a first calibration phase, the calibration logic circuit controls the first calibration signal according to a direct current (DC) signal within the amplified baseband signal, to minimize the DC signal; and
in a second calibration phase after the first calibration phase, the calibration logic circuit controls the second calibration signal according to a feedback baseband signal within the feedback signal, to minimize the feedback baseband signal.

2. The transmitter of claim 1, wherein a frequency of the baseband signal is ω₀, and the feedback baseband signal is a signal component having a frequency equal to ω₀ within the feedback signal.

3. The transmitter of claim 2, further comprising:
an analog-to-digital converter (ADC), configured to perform an analog-to-digital conversion according to the amplified baseband signal to generate a first digital signal in the first calibration phase, and perform the analog-to-digital conversion according to the feedback signal to generate a second digital signal in the second calibration phase; and
a power spectral density (PSD) circuit, coupled to the ADC and the calibration logic circuit, configured to calculate power of a signal component having a frequency equal to zero within the first digital signal to obtain a first calculation result, and calculate power of a signal component having the frequency equal to @o within the second digital signal to obtain a second calculation result, wherein the first calculation result and the second calculation result represent power of the DC signal and power of the feedback baseband signal, respectively;
wherein the calibration logic circuit controls the first calibration signal according to the first calculation result, and controls the second calibration signal according to the second calculation result.

4. The transmitter of claim 3, further comprising:
an attenuator, coupled between the analog amplifier and the ADC, configured to reduce an amplitude of the amplified baseband signal to generate an attenuated baseband signal in the first calibration phase;
wherein the ADC performs the analog-to-digital conversion upon the attenuated baseband signal to generate the first digital signal in the first calibration phase.

5. The transmitter of claim 3, further comprising:
a programmable-gain amplifier (PGA), coupled between the self-mixer and the ADC, configured to adjust an amplitude of the feedback signal to generate an adjusted feedback signal in the second calibration phase;
wherein the ADC performs the analog-to-digital conversion upon the adjusted feedback signal to generate the second digital signal in the second calibration phase.

6. The transmitter of claim 1, wherein the calibration logic circuit calibrates a first DC offset of the analog amplifier by minimizing the DC signal, and the calibration logic circuit calibrates a second DC offset of the mixer by minimizing the feedback baseband signal.

7. The transmitter of claim 1, wherein the first calibration signal source comprises:
a first calibration table, configured to record multiple first digital calibration values corresponding respectively to multiple first candidate gains of the analog amplifier, wherein the first calibration table outputs a corresponding first digital calibration value among the multiple first digital calibration values when a gain of the analog amplifier is set to a first specific gain among the multiple first candidate gains; and
a first digital-to-analog converter (DAC), coupled to the first calibration table, configured to output the first calibration signal according to the corresponding first digital calibration value.

8. The transmitter of claim 1, wherein the second calibration signal source comprises:
a second calibration table, configured to record multiple second digital calibration values corresponding respectively to multiple second candidate gains of the mixer, wherein the second calibration table outputs a corresponding second digital calibration value among the multiple second digital calibration values when a gain of the mixer is set to a second specific gain among the multiple second candidate gains; and
a second digital-to-analog converter (DAC), coupled to the second calibration table, configured to output the second calibration signal according to the corresponding second digital calibration value.

9. A method for reducing local oscillation (LO) leakage in a transmitter, comprising:
in a first calibration phase, utilizing an analog amplifier of the transmitter to amplify a baseband signal to generate an amplified baseband signal;
in the first calibration phase, utilizing a calibration logic circuit of the transmitter to control a first calibration signal source of the transmitter to output a first calibration signal to the analog amplifier according to a direct current (DC) signal within the amplified baseband signal, in order to minimize the DC signal;
in a second calibration phase after the first calibration phase, utilizing a mixer of the transmitter to perform an up-conversion upon the amplified baseband signal to generate a radio frequency (RF) signal;
in the second calibration phase, utilizing a self-mixer of the transmitter to perform self-mixing according to the RF signal to generate a feedback signal; and
in the second calibration phase, utilizing the calibration logic circuit to control a second calibration signal source of the transmitter to output a second calibration signal to the mixer according to a feedback baseband signal within the feedback signal, in order to minimize the feedback baseband signal.

10. The method of claim 9, wherein a frequency of the baseband signal is ω₀, and the feedback baseband signal is a signal component having a frequency equal to ω₀ within the feedback signal.

11. The method of claim 10, further comprising:
in the first calibration phase, utilizing an analog-to-digital converter (ADC) of the transmitter configured to perform an analog-to-digital conversion according to the amplified baseband signal to generate a first digital signal;
in the first calibration phase, utilizing a power spectral density (PSD) circuit of the transmitter to calculate power of a signal component having a frequency equal to zero within the first digital signal to obtain a first calculation result, wherein the first calculation result represents power of the DC signal;
in the first calibration phase, utilizing the calibration logic circuit to control the first calibration signal according to the first calculation result;
in the second calibration phase, utilizing the ADC to perform the analog-to-digital conversion according to the feedback signal to generate a second digital signal;
in the second calibration phase, utilizing the PSD circuit to calculate power of a signal component having the frequency equal to ω₀ within the second digital signal to obtain a second calculation result, wherein the second calculation result represents power of the feedback baseband signal; and
in the second calibration phase, utilizing the calibration logic circuit to control the second calibration signal according to the second calculation result.

12. The method of claim 11, further comprising:
in the first calibration phase, utilizing an attenuator of the transmitter to reduce an amplitude of the amplified baseband signal to generate an attenuated baseband signal;
wherein the ADC performs the analog-to-digital conversion upon the attenuated baseband signal to generate the first digital signal in the first calibration phase.

13. The method of claim 11, further comprising:
in the second calibration phase, utilizing a programmable-gain amplifier (PGA) of the transmitter to adjust an amplitude of the feedback signal to generate an adjusted feedback signal;
wherein the ADC performs the analog-to-digital conversion upon the adjusted feedback signal to generate the second digital signal in the second calibration phase.

14. The method of claim 9, wherein the calibration logic circuit calibrates a first DC offset of the analog amplifier by minimizing the DC signal, and the calibration logic circuit calibrates a second DC offset of the mixer by minimizing the feedback baseband signal.

15. The method of claim 9, wherein utilizing the calibration logic circuit of the transmitter to control the first calibration signal source of the transmitter to output the first calibration signal to the analog amplifier according to the DC signal within the amplified baseband signal in order to minimize the DC signal comprises:
controlling a first calibration table of the first calibration signal source to record multiple first digital calibration values corresponding respectively to multiple first candidate gains of the analog amplifier;
controlling the first calibration table to output a corresponding first digital calibration value among the multiple first digital calibration values in response to a gain of the analog amplifier being set to a first specific gain among the multiple first candidate gains; and
controlling a first digital-to-analog converter (DAC) of the first calibration signal source to output the first calibration signal according to the corresponding first digital calibration value.

16. The method of claim 9, wherein utilizing the calibration logic circuit to control the second calibration signal source of the transmitter to output the second calibration signal to the mixer according to the feedback baseband signal within the feedback signal in order to minimize the feedback baseband signal comprises:
controlling a second calibration table of the second calibration signal source to record multiple second digital calibration values corresponding respectively to multiple second candidate gains of the mixer;
controlling the second calibration table to output a corresponding second digital calibration value among the multiple second digital calibration values in response to a gain of the mixer being set to a second specific gain among the multiple second candidate gains; and
controlling a second digital-to-analog converter (DAC) of the second calibration signal source to output the second calibration signal according to the corresponding second digital calibration value.
